(19) United States
(12) Patent Application Publication
(10) Pub. No.: US 2002/0148941 A1
(43) Pub. Date: Oct. 17, 2002

(54) Sputtering method and apparatus for depositing a coating onto substrate

(76) Inventors: Boris Sorokov, Haifa (IL); Ilya Khanukov, Haifa (IL); Orit Khanukov, Haifa, IL (US)

Correspondence Address: BLANK ROME COMISKY & MCCAULEY LLP, THE FARRAGUT BUILDING, SUITE 1000, 900 17TH STREET, NW, WASHINGTON, DC, 20006, US

(21) Appl. No.: 09/759,491

(22) Filed: Jan. 16, 2001

Related U.S. Application Data
(63) Continuation-in-part of application No. 08/388,425, filed on Feb. 14, 1995.

(30) Foreign Application Priority Data
Feb. 17, 1994 (IL) 108677

(51) Int. Cl. B28B 7/36; C23C 14/32

(52) U.S. Cl. 249/114.1; 204/192.12; 204/298.03; 204/298.07; 204/298.08; 204/298.15; 204/298.16

(57) ABSTRACT

Sputtering method and apparatus for depositing a coating onto substrate employs variable magnetic field arranged in vicinity of a cathode within a working chamber, filled with ionizable fluid. By controlling a magnetic field topology, i.e. orientation and value of magnetic strength with respect to cathode there is enabled localization and shifting of plasma away from substrate and by thus improvement of adhesion and properties of deposited coatings.

This is a continuation-in-part application of pending application Ser. No. 08/388,425, filed Feb. 14, 1995, which in turn is based on and claims priority of Israeli Patent Application No. 108677 filed Feb. 17, 1994, the priority of which is claimed herein.

### FIELD OF THE INVENTION

The present invention relates to the coating of substrates by means of physical sputtering effect, in which the transfer of kinetic energy from ions of glow discharge plasma, striking the cathode surface leads to ejection of cathode material from the cathode and to subsequent formation of coating onto the substrate.

More particularly, the invention relates to sputtering process carried out in a diode-type apparatus, where glow discharge is established in the working chamber in an atmosphere of ionizable fluid, maintained at reduced pressure between the cathode, constituting a target, and the anode and where cathode atoms, emitted by the bombardment of plasma ions move towards the substrate, mounted in the same chamber.

The present invention also refers to articles, provided with the coating, deposited by the sputtering method.

### BACKGROUND OF THE INVENTION

The occurrence of a metallic coating which sputtered on the glass walls of a discharge tube was observed in the last century; the explanation for this phenomena at the beginning of this century, is the ejection of cathode material by positive ions striking the cathode.

Nowadays the sputtering process, which basically can be attributed to the same phenomena, is used on an industrial scale for the deposition of different kinds of coatings on different substrates. A large variety of devices has been developed for this purpose.

A comprehensive review of the physical methods of discharge sputtering deposition as well of equipment configuration, used for this purpose can be found in the monograph “Thin Film Processes”, edited by John L. Vossen and W. Kern, Academic Press, 1978, the relevant portions of which is incorporated herein by reference.

The simplest system, which is employed for deposition of films by sputtering process utilizes the glow discharge between two electrodes (cathode and anode), established within the evacuated working chamber and is commonly referred to as a diode arrangement.

The cathode in these systems is usually planar and constitutes the target, connected to a negative voltage source, capable of supplying voltage of several kV (dc or ac), while the anode is grounded. The substrate holder is mounted within the chamber and faces the cathode.

A stream of gas (the most common sputtering gas is argon) is continuously introduced into the chamber and is evacuated therefrom so as to provide a medium in which a glow discharge plasma, consisting of a gas ions, can be maintained.

The applied negative voltage urges these ions to strike the cathode, while removing its atoms by momentum transfer. The flux of these atoms moves towards the substrate, usually situated in the vicinity of the glow discharge region and condense onto the substrate surface.

In some cases gases or mixtures of gases other than argon are fed into the chamber so as to cause the deposition of a compound, synthesized on the substrate due to interaction between the atoms, which are dislodged from the cathode plate, and the reactive gas species, which are present in the chamber atmosphere.

TiO₂, synthesized by sputtering a Ti cathode in a reactive atmosphere of mixture of argon with oxygen, can be mentioned as an example of such a compound.

The main advantage, associated with the planar diode arrangement is its simplicity and possibility of applying rather high voltages to the cathode, resulting in ejection and sputtering of atoms with high energies in the range of 10-100 eV, which reach the substrate fast and thereon form a coating layer, firmly adhering to the substrate surface.

On the other hand, the high energy of plasma particles reaching the substrate is inevitably associated with exposing the substrate surface to a heat flux with high density (up to several watt per square centimeter) and heating. the substrate to high temperatures ranges from about 400-600° C.

Such high temperatures might have number of undesirable consequences, e.g.,

preclude the use of sputtering deposition for coating substrates, made of materials, susceptible to these temperatures, e.g., plastics,

cause warping in substrates with a large length-to-thickness ratio,

deteriorate adhesion between the coating and the substrate due to the development of excessive thermal stresses in the interface region, because of the difference in linear thermal expansion coefficients of the coating and the substrate,

promote undesirable chemical reactions at the substrate surface, which is exposed to plasma ions and electrons, and the subsequent formation of undesirable compounds.

The other disadvantage of the planar diode arrangement is associated with relatively high gas pressure, which should be kept within the diode source chamber, so as to maintain condition for self-sustained glow discharge. This pressure might affect dispelling of the stream of the target atoms (so-called collision scattering), moving towards the substrate, which in its turn reduces the sputtering rate and prevents the establishing of conditions for formation of homogeneous coating and might even cause deterioration of some properties of the coating.

Reducing the pressure can, to some extent, decrease the above-mentioned associated negative effects; however, this pressure cannot be kept less than a certain minimum, which is 20-100 millibars; otherwise, the density of ions required for sputtering of target atoms falls too rapidly and sputtering rate becomes too slow.

Typical sputtering conditions, employed in planar high voltage diode sources, e.g., for sputtering of Ni in Ar atmosphere, as described in the Vossen & Kern monograph are: cathode-to-substrate separation 4.5 cm, voltage 3 kV, pressure 75 millibar (7.5 KPa), current density 1 mA/cm².

It is known that in order to improve sputtering rates at low pressures the ionization efficiency of available ionizing electrons of the gas should be increased. This effect is provided in diode sources, known as magnetrons, in which a transverse magnetic field, normal to the electric field is applied to the target and is so configured that the ExB electron drift currents close on themselves.

The magnetron mode of operation is defined by magnetic focusing of the glow discharge, which results in the formation of an uniform plasma sheet over the cathode, disposed remotely from the substrate surface and thus preventing its excessive heating, seeing that the substrate is no longer subject to the plasma bombardment.

A typical diode source which operates in the magnetron mode is disclosed in U.S. Pat. No. 4,006,073, and comprises a cathode target, made of the sputtering material, a substrate holder mounted opposite said target, at least one anode, the means for supplying an ionizable gas, the means for establishing an electric field between the cathode and anode, sufficient to sustain an electrical discharge between them through said gas and means for establishing a magnetic field to extend through the space surrounding said anode and cathode.

Despite the benefits associated with the magnetron mode of operation, e.g., relatively low temperatures at the substrate surface (50-200° C.), and elimination of collision scattering effect due to reduced pressure, this configuration nevertheless suffers from certain limitations. For example, the magnetic field configuration is formed as a closed-on-itself loop, which causes a nonlinear current characteristic of the glow discharge area and does not allow application of high voltages as in planar diode sources.

The typical magnetron-mode operating conditions for magnetron type diode sources, as listed in the Vossen & Kern monograph are:

voltage 800 V, magnetic field 150 G, pressure 10⁻³ millibar

(0.1 Pa), current density 20 mA/cm².

The relatively low voltage, employed in magnetron sources is associated with reduced energy, submitted to atoms being ejected from the target and moving to the substrate with energies of several eV instead of several tenths of eV. Reduced energy of target material flux, reaching the substrate is associated with formation of less dense coating and poor adhesion to the substrate.

A further serious disadvantage of the magnetron configuration is associated with reduced service life of the target due to nonhomogeneous dislodging of cathode material and formation of regions with deep cathode erosion (local erosion profile), where magnetic and electrical fields cross. Besides shortening the service life these regions together with less eroded regions define the target topography, which prevent the possibility of achieving a homogenous flux of material ejected from the target surface. The thickness of the coating becomes nonuniform and depends on the disposition of the substrate with respect to target surface.

### OBJECTS AND SUMMARY OF THE INVENTION

An object of the present invention is to provide a sputtering deposition method and apparatus for its implementation, as well as the resulting article of manufacture, comprising substrate and coating, deposited by this method using the apparatus, in which the above mentioned drawbacks of planar diode and magnetron diode modes of operation are sufficiently reduced or overcome, without losing, however, the benefits associated with each of these configurations.

In particular, the first object of the present invention is to provide new, simple and improved sputtering deposition method and apparatus, in which plasma is shifted away from the substrate and the substrate surface is not exposed to heat with high density so as not to undergo heating over 200-300° C.

Another object of the present invention is to provide a new and improved sputtering deposition method and apparatus, in which the pressure of gas supplied to the chamber does not exceed (1-7)¹⁰⁻³ millibars sufficient, however, for maintaining a self-sustained glow discharge and deposition with high sputtering rate.

Another object of the present invention is to provide a sputtering deposition method and apparatus, in which relatively high voltage, i.e., several kV, can be applied to the cathode, while employing a magnetic field for focusing and localizing the glow discharge area.

Another object of the present invention is to provide a sputtering deposition method and apparatus, in which formation of local erosion profile through the target surface is sufficiently reduced, so as to improve the target service life, to achieve homogeneous ejection of target material and formulation of uniform coating on the substrate, irrespective of mutual disposition of the substrate and the target.

Still another object of the present invention is to provide a sputtering deposition method and apparatus, as well as articles of manufacture, having a firmly adhering coated substrate with improved structure properties.

Yet another object of the present invention is to provide a mold for the manufacture of molded optical articles, e.g., a silica coated glass substrate, deposited by the sputtering deposition method and apparatus of the present invention in which the coating has improved density, chemical resistance and optical properties.

The above and other objects and advantages of the present invention can be achieved in accordance with the following combination of its essential features, referring to embodiments of the present invention as a method, apparatus for its implementation and article of manufacture, produced in the apparatus for carrying out the method.

The method of depositing a coating onto a substrate by means of a sputtering process wherein a glow discharge plasma is generated in diode sputtering source between a cathode, provided with outwardly facing surface, constituting a target, and an anode, and wherein establishing of said plasma results in ion bombardment of said target, followed by ejection of target material and its movement towards said substrate with subsequent formation of a coating, depositing onto said substrate,

whereas said method comprises the following steps:

introducing a to-be-coated substrate, into the process chamber so as to expose the surface of said substrate to the flux of the sputtered target material,

establishing a magnetic field within the chamber,

applying to the cathode electrical power sufficient to establish a glow discharge plasma,

establishing within the chamber an atmosphere of ionizable fluid, continuously fed therein and evacuated therefrom so as to establish a working pressure, sufficient for maintaining the glow discharge plasma consisting of fluid ions,

maintaining between the anode and cathode, a self-sustained glow discharge accompanied by the generation of an ion plasma which bombard the target and emits target material towards the substrate,

varying the magnetic field so as to achieve topology of its magnetic lines, defined by magnetic strength vector arbitrary oriented with respect to the anode and defined by magnetic strength in the range of 10-100 kA/m within the region, situated adjacent to the anode and in the range of at least 8-10 kA/m adjacent to the target and within a region, having the configuration of a layer, extending above the outwardly facing target surface. The layer has a thickness in the range of 2-5 cm. The magnetic field is varied so as to localize and shift the plasma substantially away from said substrate.

In accordance with one of the preferred embodiments of the method, electrical power is supplied by means of dc or ac supply, being capable of supplying to said diode source voltage in the range of 1-5 kV, said magnetic field being established by means of solenoids or permanent magnets.

According to a further preferred embodiment, the ionizable fluid is continuously fed within said chamber so as to monitor therein a working pressure in concert with variations in electrical power and/or magnetic field. The ionizable fluid consists of an inert and/or reactive gas which is maintained at less than 1 Pa, preferably in the range of 0.1-0.7 Pa working pressure.

In accordance with a further embodiment of the present invention, there is provided an apparatus suitable for depositing a coating onto the substrate by means of a diode sputtering source wherein a glow discharge plasma is generated between cathode, constituting a target, and anode, which results in ion bombardment of the target, followed by liberation of target material and its ejection and transport towards the substrate with subsequent formation of a coating onto said substrate.

The apparatus of the present invention comprises:

a vacuum chamber containing an atmosphere of ionizable fluid fed within said chamber at a controlled reduced pressure;

a cathode pole structure, positioned within said chamber and defined by an outwardly facing surface, constituting a target, composed of material to be ejected therefrom;

an anode, insulated electrically from said cathode pole structure and situated within said chamber so as to provide diode arrangement with said cathode pole structure;

an electric power supply means for applying electrical potential between said target and said anode, and sufficient for establishing and maintaining a self sustained plasma glow discharge between them;

at least one substrate holding means, mounted within said chamber and positioned so as to expose the substrate to the flux of target material ejected therefrom;

means for supplying ionizable fluid into said chamber and its evacuation therefrom so as to maintain within the chamber the atmosphere of the fluid at pressure sufficient for maintaining said plasma glow discharge;

a magnetic field generator positioned for establishing magnetic field within the chamber;

appropriate controls and instrumentation for monitoring electrical and magnetic parameters of the power supply and the magnetic field generator;

wherein the magnetic field generator means is situated substantially adjacent to the anode and generates a magnetic field with topology defined by magnetic strength vector arbitrary oriented with respect to the anode and having a magnetic strength gradient within the interior of the chamber in the range of 10-100 kA/m in the vicinity of the anode and in the range of at least 8-10 kA/m in the vicinity of the cathode within a region, extending above the target surface and having a thickness of 2-5 cm.

According to one of the preferred embodiments of the present invention, the electrical power supply is a dc supply which supplies the diode voltage in the range of 1-5 kV. The magnetic field generator may be solenoids or permanent magnets. The present apparatus includes a pressure controller for monitoring pressure within the chamber in accordance with variation of parameters of the electrical power supply and/or magnetic field generator. The target material is a metallic element the said ionizable fluid is a mixture of argon and oxygen. The outwardly facing target surface of the cathode pole structure is formed as a body, defined by central symmetry with respect to its center of symmetry. The anode is formed as a body, having rotational symmetry with respect to its central axis of symmetry. The anode surrounds the cathode pole structure. The substrate holding means is formed as a body, having central symmetry with respect to its center of symmetry. The substrate holding means is provided with a plurality of holding stations arranged thereon for fixation of a plurality of substrates. The cathode pole structure, the anode and the substrate holding means are arranged in such a manner, that both said centers of symmetry of the target surface and the substrate holding means and the central axis of symmetry of the anode substantially coincide.

The cathode pole structure is formed as a spherical segment and the substrate holding means is formed as a truncated icosahedron.

The resulting article, manufactured within the apparatus using the present method comprises a substrate and a coating deposited onto the substrate. The coating is formed on the surface of the substrate due to interaction of material, sputtered from the cathode target with the ionized reactive fluid, fed into the source; wherein sputtering of the material towards said substrate is effected by glow discharge plasma magnetically shifted away from the substrate and the coating, deposited onto the substrate is formed at temperatures not exceeding 300° C., preferably 40-200° C. The coated article can be a mold for manufacturing optical articles. The mold is formed of a glass substrate having a SiO₂ coating thereon.

By virtue of the combination of high voltage applied to the diode source and magnetic focusing and shifting of plasma away from the substrate, the energy is imparted to the sputtered atoms more efficiently so that the deposition results in a highly adherent coating without excessive heating of the substrate. Indeed, without the use of cooling, the substrate temperature does not exceed 200° C. using the method of the present invention compared with 400° C.-600° C. substrate temperatures experiences with conventional processes. This results in improved coating densities, homogeneity, chemical resistance and improved adhesion.

For example, the hardness of the resulting aluminum oxide coating s (Vickers) are over 300% harder than oxide coatings obtained using conventional magnetron sputtering. Similarly, lower friction coefficients (about 1.4 vs. about 0.28) are obtained with alumina coatings using the present method.

The aforementioned improvements result in part from the fact that the substrate does not contact the anode, nor require a supply of coolant to the substrate holder. Instead, the lower substrate temperatures are obtained by the use of a stationary, strong, nonuniform magnetic field with dedicated topology, defined by a gradient of magnetic strength of 1.25-4.5 which permits focusing the plasma and dislocation of electrons remote from the substrate, such that, they are separated therefrom by a distance of 1-20 cm, preferably 2-10 cm. The result of this arrangement is that the substrate is free from thermal or chemical influence since the plasma is directed away from the substrate.

Stated another way, the method according to the present invention creates a magnetic trip which captures the plasma within a space between the anode and cathode at a distance of 5-8 cm from the substrate. This trap is created within the glow discharge area of a stationary nonhomogeneous magnetic field of about 10-40 KA/m. The magnetic strength in the area adjacent to the anode exceeds the magnetic strength adjacent to the target by about 100 to 400%.

For better understanding of the present invention as well of its advantages, reference will be now made to the following description of its embodiments, taken in combination with accompanying drawings, tables and examples.

### BRIEF DESCRIPTION OF THE DRAWINGS

FIG. 1 is a schematic representation illustrating apparatus for sputtering deposition according to the present invention.

FIGS. 2(A), 2(B), 2(C) are graphs which show the operating characteristics of the sputtering deposition method according to the present invention in comparison with sputtering in a planar diode source.

FIGS. 3(A), 3(B) show properties of the coatings deposited by the sputtering method according to present invention.

FIGS. 4(A), 4(B), 4(C) illustrate the relative disposition of cathode, anode and substrate holding means according to apparatus of the present invention for simultaneous deposition on a plurality of substrates.

FIG. 5 is an isometrical view of one of the embodiments of a substrate holding means used for simultaneous deposition on a plurality of substrates.

FIG. 6 illustrates a coated article of manufacture coated in accordance with the present invention.

FIG. 7 shows the distribution of the thickness of coatings, deposited on a plurality of articles, shown in FIG. 6 and fixed in the substrate holding means, shown in FIG. 5.

FIG. 8 is a schematic representation of a silver reflector coated in accordance with the present invention.

FIG. 9(A) is another schematic representation of apparatus according to the present invention operated according to Example 3 using a spherical target.

FIGS. 9(B) and 9(C) are graphs and tables, respectively, of measurements taken using the apparatus of FIG. 9(A).

FIG. 10(A) is another embodiment of apparatus according to the present invention operated according to Example 3 using a flat target.

FIGS. 10(B) and 10(C) are graphs and tables, respectively, of measurements taken using the apparatus of FIG. 10(A).

### DETAILED DESCRIPTION OF SPECIFIC EMBODIMENTS

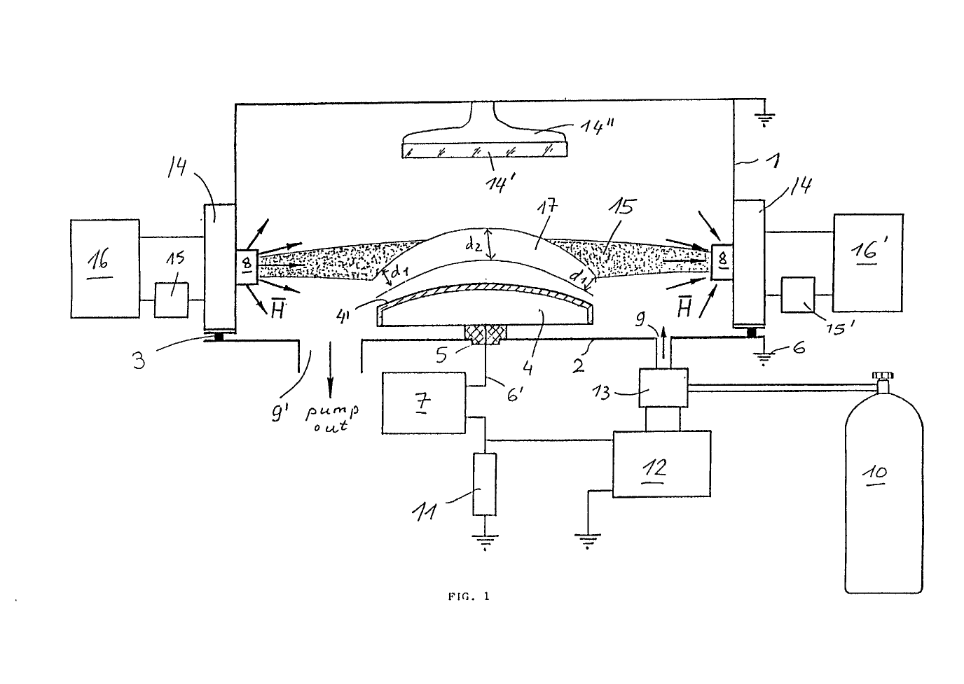

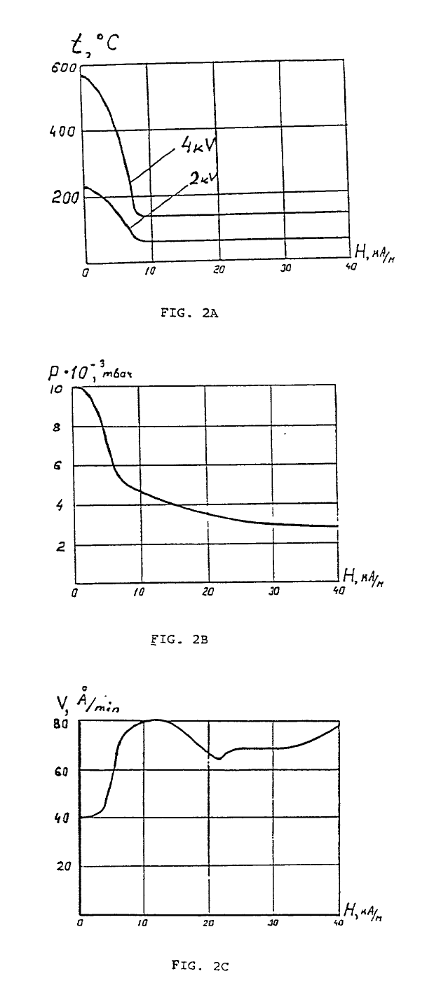

With reference to FIG. 1, a sputtering assembly, suitable for implementation of sputtering deposition method according to present invention comprises a working chamber 1, resting on a platform or base 2 and insulated therefrom by vacuum tight sealing 3. Cathode pole structure 4 is mounted within the chamber on the pedestal 5, made of electrically insulating material so as to insulate the cathode from the chamber. The housing is wired to the ground 6 and cathode pole structure is connected by line 6′ to power supply unit 7, capable of supplying negative voltage in the range of several kilo volts.

Annular anode 8 is preferably arranged within the chamber so as to provide for a distance of at least 2 cm from cathode and to provide for appropriate electrical conditions, sufficient for generating of glow discharge in the area between cathode and anode after the chamber is evacuated and degassed and electrical power is supplied to the cathode.

It should be understood that instead of annular anode a pair or several planar anodes can be employed as well.

There are provided an inlet port 9, connected with the source 10 of appropriate ionizable gas to be introduced into the chamber, and an outlet port 9′ for pumping out and evacuation of the gas therefrom by appropriate pumping means (not shown). Simultaneous supply of gas and its evacuation enable maintenance of the gas atmosphere within the chamber at certain pressure sufficient for establishing a self-sustaining glow discharge between cathode and anode, and the generation of plasma, consisting of positive gas ions.

The magnitude of current, developed during generation of plasma, is continuously sensed and measured by appropriate current sensing means 11, which is connected with power supply unit 7 and with cathode current regulating unit 12, enabling control of supplied voltage so as to maintain conditions for self-sustained glow discharge. The amount of gas, supplied from source 10 is supervised by control valve 13, connected to the same regulating unit 12 so as to control amount of gas to enter in accordance with fluctuations of electrical parameters within the chamber.

Immediately after establishing of glow discharge in the area between cathode and anode, the positive plasma ions are attracted by negative potential, supplied to cathode pole structure, and continuously bombard its outwardly facing surface 4′, constituting a target. Atoms of target material, dislodged therefrom by striking atoms and having energies of 10-100 eV are sputtered toward the oppositely situated substrate 14′, mounted on the substrate holding means 14″, arranged within the chamber. The substrate surface is coated by atoms sputtered from the cathode.

The composition of the substrate coating depends on the composition of target material and the gas atmosphere within the chamber. The sputtered target atoms which move toward the substrate may interact with gas ions and form compounds, which then deposit on the substrate instead of forming a coating consisting of only the target atoms.

In accordance with the present invention, the gas atmosphere within the chamber and target composition may be chosen to provide for the deposition of either atomic or compound coating or both. For example, it has been empirically found that this invention is particularly advantageous for the sputtering of compound oxide coatings, comprising combinations of silica, alumina, SnO₂, Ta₂O₅. For this purpose, the reactive gas comprising a mixture of inert gases with oxygen, is fed into the chamber and the target material is a suitable metallic element such as Si, Al, Sn, Ta, etc.

It should be understood, however, that the present invention is not limited by deposition of oxides and that by proper selection of reactive gas atmosphere (e.g. nitrogen, ammonia, acetylene, etc.) and the composition of the target material, the resulting coating may also include non-oxide compounds, such as nitrides, carbides, borides, silicides, etc.

As can be seen in FIG. 1 the outwardly facing target surface 14′, is defined by a curvilinear convex shape; however, this shape can be defined by a concave or concave/convex curvilinear configuration, planar configuration, etc.

The target can be formed integrally with the cathode structure or constitute a layer of foil, plate or deposit, supported by this structure.

It is not shown in detail, but it should be understood that the appropriate means for cooling of cathode structure and/or substrate holding means might be provided, so as to improve dissipation of the heat generated during the sputtering process. The high voltage power supply unit, suitable for employment in the present invention can be any type known in the art as being sufficient for glow discharge sputtering, e.g., DC supply, low-frequency AC supply or RF supply.

The assembly is provided with a magnetic field generating means 14, arranged substantially in proximity with anode 8, so as to establish magnetic field within the chamber, schematically shown by dotted area 15. The magnetic field generating means 14, shown in FIG. 1 is formed as a system of solenoids with windings, connected with current control means 15,15′ for adjusting magnetic field by variation of current, supplied by current supplies 16,16′. It should be understood, however, that permanent magnets, having suitable magnetic parameters can be employed as well for generation of magnetic field. In contrast to conventional magnetron diode sources, which are also provided with magnetic field generating means and where magnetic field is configured with respect to the cathode surface so as to trap electron currents by closing them on themselves, the magnetic field 15 in accordance with the present invention is configured and maintained in such a manner, that its vector of magnetic strength is arbitrarily oriented with respect to anode 8, as shown by arrows H. By virtue of this configuration the electron currents in plasma are not closed on themselves anymore; thus, there is enabled a magnetic focusing of the plasma within the localized region, which can be deliberately shifted away from the substrate holding means. By virtue of this configuration of magnetic field and by proper selection of magnetic strength, as it will be further explained in more details, heating of the substrate is eliminated, or at least is sufficiently reduced, as compared to known sputtering sources.

In order to achieve the most optimal condition for focusing of plasma the magnetic parameters of the magnetic field generating means 14 are varied so as to achieve a nonuniform magnetic field, defined by variable magnetic strength within the chamber. In accordance with the present invention the magnetic strength gradient should be established within the chamber in such a manner that magnetic strength in the range of 10-100 kA/m is within the area, situated in the vicinity of said anode and in the range of at least 8-10 kA/m within the area, situated in vicinity of said cathode pole structure. It has been empirically found that it is especially advantageous, if the region of magnetic strength of 8-10 kA/m is concentrated within the cathode glow area and the best results are achieved if parameters of magnetic field generating means are chosen so as to configure the cathode glow area as a layer, substantially similar to that of outwardly facing target surface and having a thickness of 2-5 cm.

With reference to FIG. 1 the cathode glow area 17 is shown, in which the magnetic strength is kept in the range of 8-10 kA/m and as can be seen this area is defined by a layer with a saddle—like shape, configured similarly to the outwardly facing target surface 4′.

The thickness of this layer varies from a minimum value dl of approximately 2 cm at lateral portions to a maximum d2 of approximately 5 cm in the middle. It should be understood, however, that proper selection of magnetic parameters, satisfying described above condition of magnetic strength gradient, might result in the cathode glow area being configured differently so as to correspond with the target surface of a different shape.

It is shown in FIG. 1 that the magnetic field generating means 14 are situated adjacent to anode 8 and outside the working chamber 1. It should be understood, however, that these means can be arranged within the chamber as well.

It has been empirically revealed, that by applying the magnetic field to the diode source in accordance with the above described conditions, the self-sustaining discharge between cathode and anode can be reliably maintained at sufficiently reduced pressure, compared to that used in conventional planar anode sources.

In particular, it has been shown that, if the applied voltage is in the range of 2-5 kV and the reactive gas atmosphere within the chamber is a mixture of argon with oxygen, the pressure of reactive gas, sufficient for generating of plasma and sputtering of target material should be less than 1 Pa, preferably 0.1-0.7 Pa. This pressure is significantly less than that require in conventional high voltage planar diode sources. For maintaining of gas atmosphere within the chamber at such a pressure the reactive gas is continuously fed from source 10 through valve 13 and is simultaneously pumped out via port 9′. As has already been mentioned the coordinated operation of valve 13 and pumping means is ensured by control unit 12 in accordance with electrical parameters of the glow discharge, establishing in the source.

The combination of high voltage with relatively low reactive gas pressure enables efficient sputtering, seeing that scattering collision effect becomes less significant. The energy submitted to sputtered atoms in a high voltage source will be spent more extensively for coating formation and adhesion. At the same time provision of magnetic focusing of plasma and its shifting away from the substrate prevents its overheating which could have taken place in a high voltage sputtering process.

It has been observed that the substrate temperature reached during deposition of oxide coatings in the sputtering apparatus according to the present invention, did not exceed 200° C. compared to 400-600° C. substrate temperatures associated with conventional high voltage diode sources.

The invention will now be described herein in the following non-limiting examples.

### EXAMPLE 1

The substrate 14′ is mounted on the substrate holding means so as to face the target surface 4′ and to be spaced therefrom by a distance 5-20 cm.

The chamber 1 is sealed; its interior is evacuated up to pressure 0.001-0.004 Pa.

The current supply 16 is initiated and parameters of magnetic field are adjusted by means of a control means 15, so as to create a magnetic strength gradient, sufficient for localization of plasma within a region, separated by a distance of 3-15 cm from the substrate 14.

The power supply 7 is initiated and a potential of 2-5 kV, negative with respect to grounded chamber 1 is supplied to the cathode pole structure 4.

By means of current sensor 11 the value of discharge current is adjusted and the stream of reactive gas mixture is fed into the chamber from the source 10, up to building working pressure, sufficient for maintaining of self-sustained glow discharge. Particular parameters suitable for deposition of Al₂O₃ coating on stainless steel substrate were:

Supplied negative voltage: 3 kV

Discharge current: 300 mA

Working pressure of gas atmosphere: 0.15 Pa (0.0015 mbar)

Reactive gas mixture: 80% Oxygen and 20% argon

Target material: Aluminum

Magnetic field strength in vicinity of anode: 40 kA/m

Magnetic field strength in vicinity of target surface: 12 kA/m

### EXAMPLE 2

In this example, it will be explained how substrate temperature, reactive gas pressure and deposition rate depend on magnetic strength in the vicinity of the target, established during sputtering and configured in accordance with the present invention. Sputtering conditions:

Water cooled cathode, made of stainless steel, provided with Al target, having

square configuration 100×300 mm.

Anode-cathode distance: 60 mm

Reactive gas: mixture of 80% argon with 20% oxygen

Supplied voltage: 4 kV or 2 kV

Supplied power: 1.2 kW and 0.6 kW respectively

Resulting coating: Alumina This positive effect might be attributed to favorable conditions associated with formation of the coating, seeing that reduction of deposition temperature directly and indirectly influences coating properties and adhesion of the coating to the substrate.

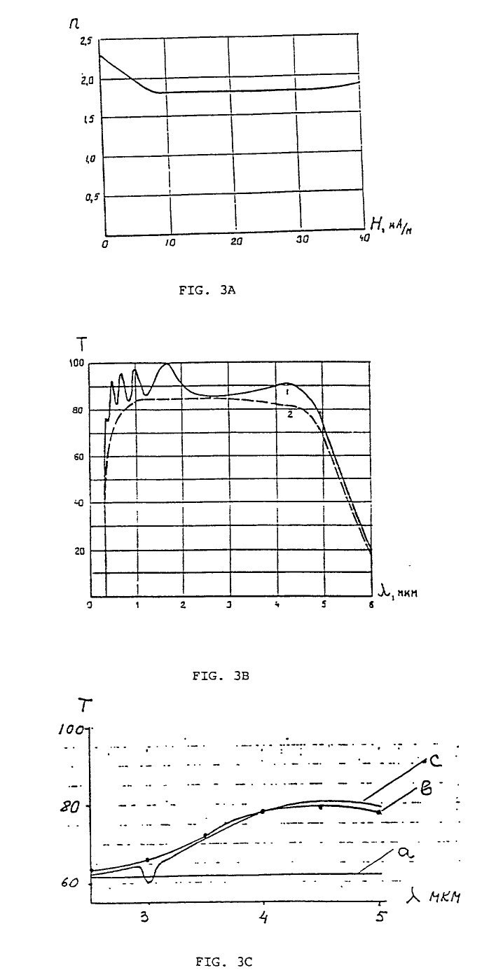

In FIG. 3(A), it is shown that the refraction index (n) of the Ta₂O₅ coating, deposited in accordance with the above conditions, diminishes, depending on magnetic field strength (H) within the cathode glow area. It can be seen that transparent amorphous coating with low refraction index was obtained.

FIG. 3(B) presents the transmittance measurements, carried out in accordance with the ASTM F 768-82 on 6 mm-thick glass plates coated on both sides with a 0.8 μm-thick silica, in accordance with the present invention. Transmittance (T) is shown by solid lines for coated glass and by dotted lines for uncoated glass. It can be clearly seen that transmittance of glass with silica coating is improved, as compared with uncoated glass. Transmittance has a uniform value of at least 85% in the wide range of wavelengths 0.3-6 μm.

FIG. 3(C) shows transmittance (T) in the range of near IR—middle IR spectrum for pure silicon, taken as a reference (curve a), for silicon, coated with a 0.8 mm-thick layer of silica, deposited in accordance with the present invention (curve b) and by conventional electron beam deposition method (curve c). It can be clearly seen, that at the wavelength of about 3 μm, the curve c exhibits sharp reduction of transmittance up to a certain minimum. This phenomena is explained by absorption of IR radiation due to the presence of water absorbed by the coating. That is, the structure of the coating deposited by conventional electron beam deposition, is porous.

In contrast to the above, the transmittance curve, obtained for a coating obtained using the present sputtering deposition method (curve b) does not exhibit such a minimum which indicates that this coating is more homogeneous and dense.

### EXAMPLE 3

This example demonstrates that the coatings deposited by the present sputtering deposition method possess good chemical resistance. The following conditions were employed:

Water cooled cathode with diameter 60 mm.

Supplied negative voltage: 2 kV

Discharge current: 300 mA

Reactive gas mixture: 80% Oxygen, 20% Argon

Working pressure: 0.004 mbar

Target material: Si

Substrate material: Kronglass

Magnetic field strength in vicinity of anode: 40 kA/m

Magnetic field strength in vicinity of target surface: 12 kA/m

Resulting coating: SiO₂

To evaluate the chemical resistance, coated and uncoated glass samples were exposed to 80% solution of sulfuric acid at 80° C. for 8 hours and concentration of certain elements was measured before and after exposure within the sample. The uncoated samples were made of Kronglass. A 0.4 μkm-thick SiO₂ coating was deposited on both sides of the sample.

Si, Na and K concentrations were measured using the EDS method within the 4 μm-thick surface layer, including the coating.

Table 2 summarizes the chemical composition of a surface layer, as measured for coated and uncoated samples before and after exposure, as well as the relative change of the surface layer composition (in percent).

TABLE 2

| | Uncoated sample | | | Coated sample | | |
|---|---|---|---|---|---|---|
| | before | after | relative | before | after | relative |
| Element | exposure | exposure | change | exposure | exposure | change |
| Si | 39.9 | 38.2 | −4.3 | 45.7 | 45.6 | −0.2 |
| Na | 2.6 | 3.5 | 34.6 | 1.8 | 1.6 | −11.1 |
| K | 57.5 | 58.3 | 1.4 | 52.5 | 52.8 | 0.6 |

As can be clearly seen from Table 2, the deposition of silica on Kronglass using the present invention resulted in much less variation of the surface layer composition, associated with very slow chemical interaction during exposure. This phenomena can be explained by firm adhesion of the coating and its good chemical resistance.

The obtension of dense coatings with improved properties, good chemical resistance and without excessive heating of the substrate are advantageous for many kinds of articles, including cemented carbide cutting tools, ceramics, etc. However, it is of particular importance for such articles like glass or steel molds for manufacturing of optical articles, plastic optical lenses and the like.

These articles are mass produced and the need to obtaining coated molds with uniform thickness and isotropic properties is critical. The known magnetron sources, suitable for coating of plurality of articles during the same run, employ various types of substrate motion relative to the target. This is inevitably associated with the complicated design of the substrating holding means and the inefficient utilization of working space within the chamber.

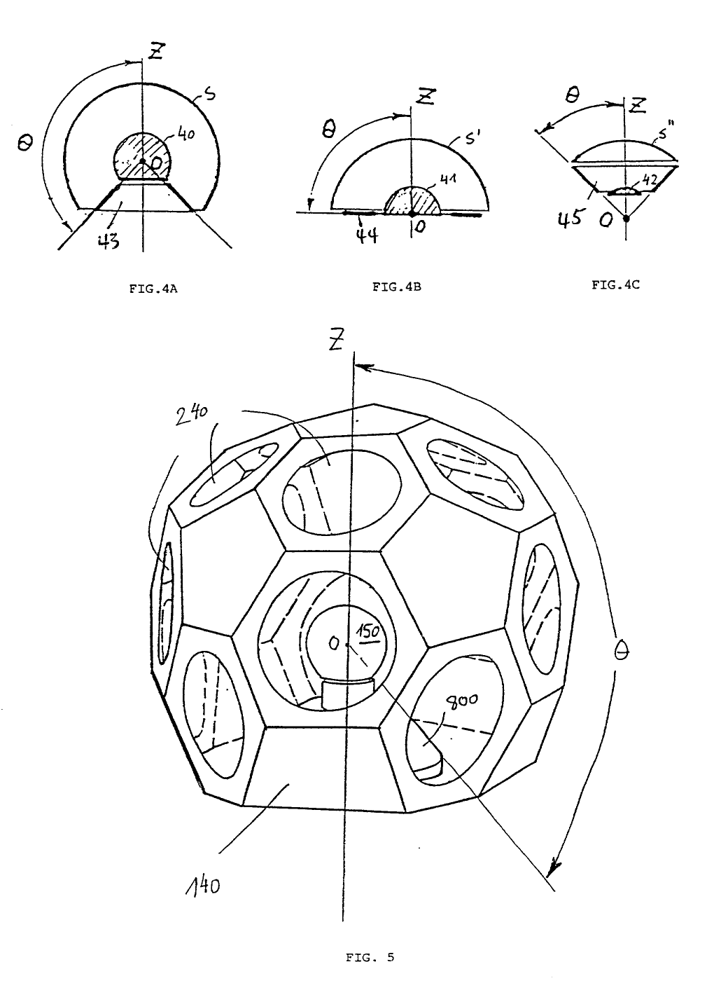

With reference to FIGS. 4(A), 4(B), 4(C) and 5, it will now be explained how the present sputtering deposition method and apparatus provide for most advantageous conditions in terms of homogeneity of target erosion and uniformity of the coating obtained on plurality of substrates without their movement. A plurality of articles are situated on the substrate holding means so as to face the cathode pole structure and to be exposed to the sputtering material, originating from its outwardly facing target surfaces 40,41,42. In order to enable sputtering of a plurality of substrates the outwardly facing target surface is configured as a spherical segment with center 0. The articles are arranged on the substrate holding means in such a manner that they become in a vis-a-vis disposition with respect to the target surface within a spherical space region S,S′,S″, which is equidistant with the target surface. The anode is formed as a body, having axis of rotation Z, passing through center 0. The anode surface is configured as a truncated cone 43 (FIG. 4(A), or a disc 44 (FIG. 4(B), or an inverted truncated cone 45 (FIG. 4(C). It should be understood that in all these embodiments the anode surrounds the cathode pole structure and the disposition of plurality of articles within a spherical space region S,S′, S″ can be defined by a declination angle θ, confined between the axis Z and the anode.

It is particularly advantageous to position the anode surface with respect to the cathode pole structure in such a manner that its imaginable apex (truncated cone configuration) or its center (disc configuration) coincides with the center 0 of the spherical target surface 40,41,42.

By virtue of the nonuniform magnetic field configured in accordance with the above defined parameters, there is no formation of locally eroded regions on the target surface and therefore the flux of material ejected from the target and directed toward the substrate is kept homogeneous.

It has been empirically established that provision of homogeneously eroding target in combination with above described configuration and disposition of target surface, anode surface and substrate holding means enables deposition of uniform coatings on a plurality of substrates, arranged within spherical space region, having a wide declination angle. θ°<0<150°, which allows utilization of the working space in a most efficient way.

Now, with reference to FIGS. 5, 6, particular implementation of the present invention for sputtering deposition of an uniform coating on a plurality of articles, will be described in more detail. The cathode pole structure is formed as a body, having central symmetry and is provided with a target, having an outwardly facing surface, formed as spherical segment 150 with center 0. An anode 800 is formed as a truncated cone and is mounted with respect to cathode pole structure in such a manner that its axis of symmetry Z coincide with the center 0 of the target surface. The substrate holding means 140 is formed as a thin walled stainless steel structure, having the configuration of a truncated icosahedron, situated in such a manner that its inwardly facing surface faces the outwardly facing target surface and defines a space region, surrounding the target surface within an inclination angle 0 confined between axis Z and conical anode. Those faces of the icosahedron structure, which have six edges constitute a plurality of holding stations 240 for fixing thereon a plurality of substrates. It is advantageous if the target surface 150 and substrate holding means 140 constitute bodies with central symmetry, while anode 800 constitutes a body with rotational symmetry along axis Z. In accordance with the present invention the substrate holding means is disposed with respect to target surface in such a manner, that centers of symmetry of target surface 150 and substrate holding means 140 coincide and lie on axis Z. By virtue of this disposition an uniform coating is obtained during the same run on a plurality of substrates, occupying a plurality of holding stations.

It should be understood that the substrate holding means can be formed not only as an icosahedron, but also as a dodecahedron, octahedron or other body, defined by its center of symmetry, providing that it has enough faces for disposing thereon a plurality of articles to be coated. In order to increase the output the apparatus can be equipped with several cathode pole structures and/or substrate holding means.

Despite the present invention being suitable for the deposition of coatings on different articles, it might be especially advantageous to implement the present invention for the deposition of a coating on a plurality of such articles, such as, molds for the manufacture of plastic optical lenses. A pair of such molds 60,61, constituting a set is shown in FIG. 6. The lens is produced by pouring a monomer liquid into the space 62, defined between concave/convex working surfaces 63,63′ of molds and then by sealing the space and polymerization of the monomer therein.

The molds are made of glass and their performance in terms of service life is influenced inter alia by working surface structure and by its chemical resistance.

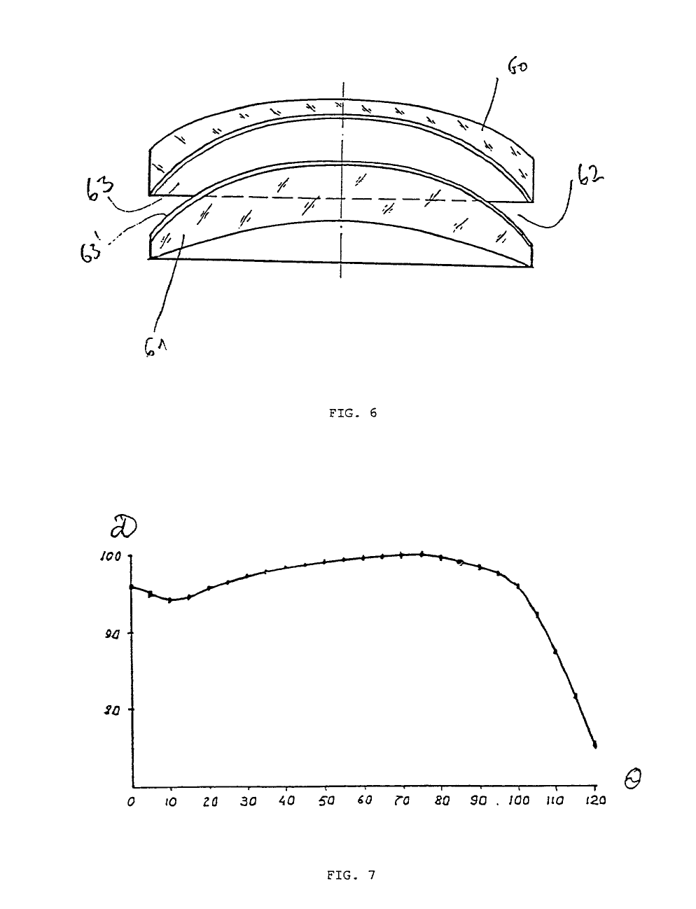

It has been already shown, that deposition of SiO₂ coating on Kronglass results in improvement of chemical resistance of the surface layer. This fact was successfully implemented for coating of molds, made of Kronglass. The deposition was carried out in accordance with the sputtering conditions, described in Example 3 within the apparatus, equipped with spherical target and icosahedron holding means, as shown in FIG. 5. FIG. 7 illustrates the deviation (D) of the coating thickness in % of nominal thickness as a function of the location of the mold within the chamber, expressed as a declination angle θ. It can be seen that deviation of the thickness did not exceed several percent within wide range of declination angle 0 from about 10 up to 100 degrees.

### EXAMPLE 4

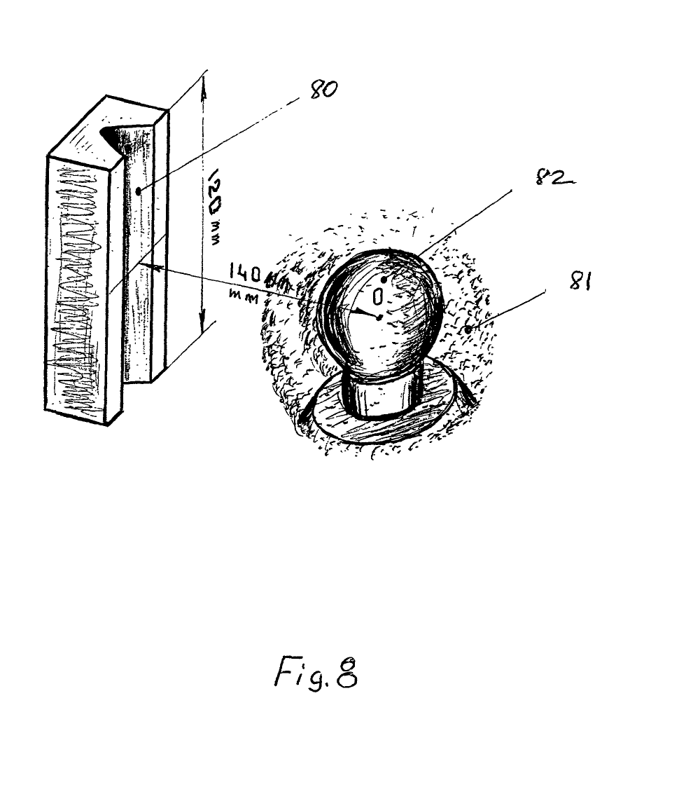

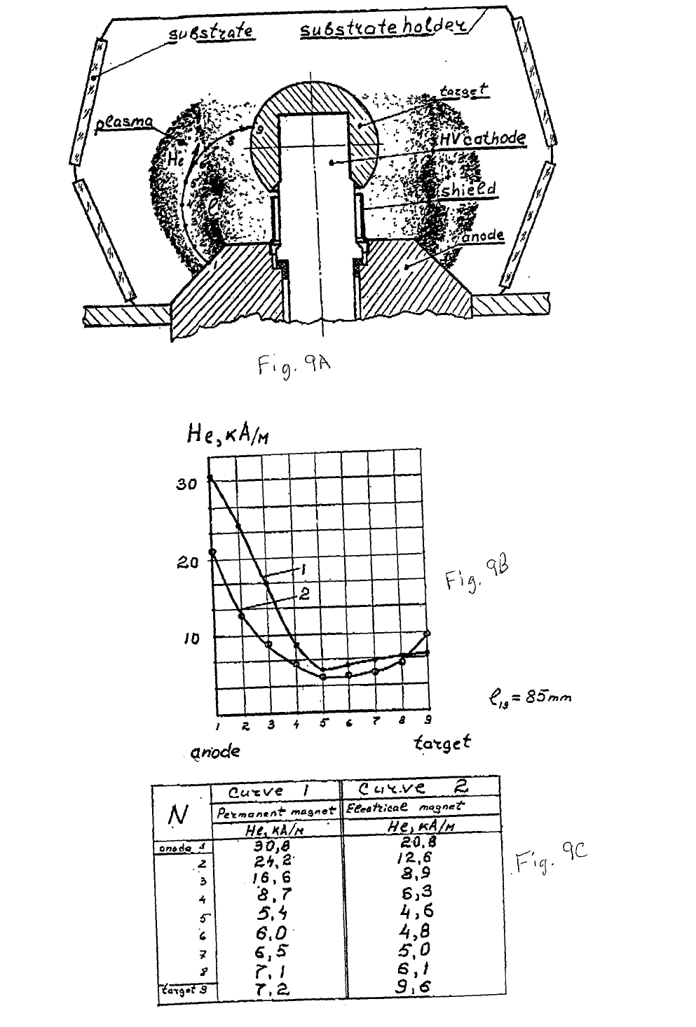

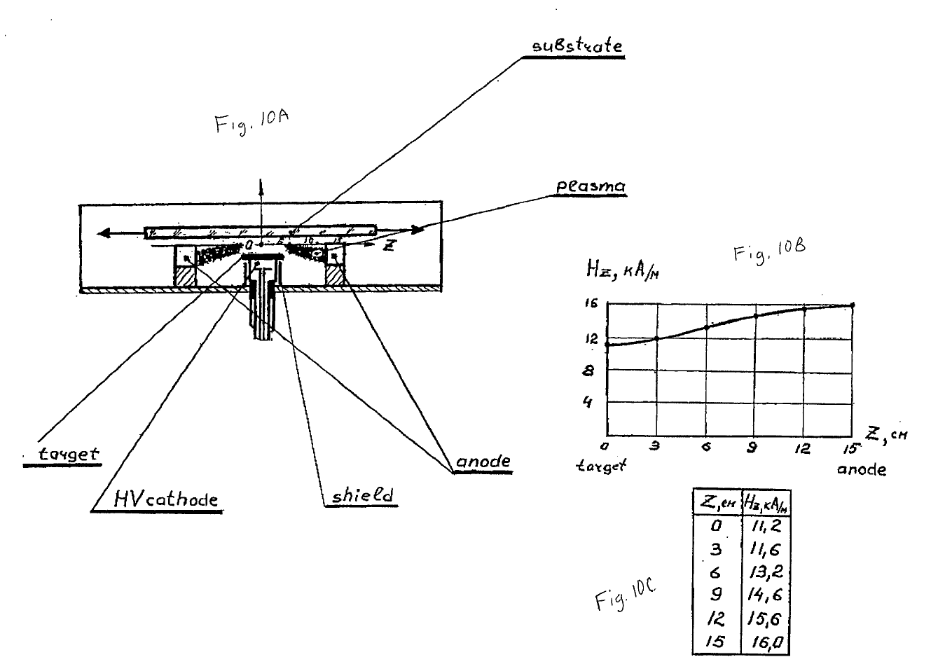

In this example, sputtering of silica film on a reflector of high power flash lamp used for UV radiation in medical application was carried out. The reflector is shown in FIG. 8. It is made of aluminum coated by a thin layer of silver. In use, the reflecting silver layer undergoes enhanced corrosion in the air atmosphere due to extensive heating and due to UV radiation. To increase the service life of such reflectors, protective coatings are applied by ensuring that the plasma is removed from the silver surface and the temperature of deposition does not exceed 30-40° C. As shown in FIG. 8, the silver coated substrate 80 is remote from the plasma region by a distance of 140 mm. By virtue of this distance it was possible to deposit a protective silica coating on the reflector surface from the Si target 82 without deterioration of the delicate silver coating under the following conditions:

| | |
|---|---|
| Sputtering voltage, KV | 2 |
| Glow discharge current, mA | 150 |
| Diameter of spherical cathode, mm | 60 |
| Thickness of protective silica coating, microns | 0.2 |
| Temperature of reflector during sputtering, deg. C. | 40 |
| Composition of gas atmosphere, % | |
| oxygen | 80 |
| argon | 20 |
| Pressure during deposition, mbar | 0.002 |

The resulting coated silver reflector surface possessed improved corrosion resistance.

### EXAMPLE 5

In this example, a protective coating was formed on chucks of machines used for treating silicon wafers. It is known that processing of silicon wafers requires very high cleanliness within the working space. Mechanical parts which are in physical contact with wafers must be resistant to wear so as not to add micro particles to the atmosphere due to friction. The chucks are manufactured from aluminum alloys which are anodized to form hard alumina protective coating. After anodizing, the chucks are lapped to very high levels of flatness. However, anodically produced alumina coatings are not sufficiently resistant to wear. Adding a protecting coating by conventional sputtering may cause worsening of flatness due to heating, deformation or erosion. By virtue of the present invention, it was possible to sputter alumina and silica protective coatings onto chucks without heating, erosion or deformation, under the following conditions:

| | |
|---|---|
| Sputtering voltage, KV | 2 |
| Glow discharge current, mA (two guns) | 600 |
| Thickness of protective silica coating, microns | 1.5 |
| Temperature of part during sputtering, deg. C. | 90 |
| Pressure during deposition, mbar | 0.002 |

By using chucks with sputtered coatings, it was possible to reduce the concentration of micro particles by several times in the clean rooms used to make semiconductor wafers.

### COMPARATIVE EXAMPLES

The following comparative Examples 6 and 7 demonstrate that the ceramic film deposited in accordance with the present invention has a significantly higher hardness than the same coating material deposited using conventional magnetic sputtering described by Jones et al. (J. Vac. Sci. Technol., Vol. 7, No. 3, May/June 1989, p. 1245).

### EXAMPLE 6

Polycrystalline alumina rods having a 1.6 mm diameter with conical tips were coated with amorphous alumina. The deposition process was carried out using the apparatus described herein under the following conditions:

| | |
|---|---|
| Discharge voltage | 2 kV |
| Discharge current density | 4 mA/cm² |
| Target working area | 100 cm² |
| Target material | Aluminum |
| Distance between the target and rod tip | 60 mm. |
| Substrate temperature | 80 degrees C. |
| Magnetic field strength | 6 kA/m |
| Gas mixture | 20% Argon, 80% Oxygen |
| Gas pressure | 2 × 10⁻³ mbar |
| Thickness of deposited alumina film | 0.5 micron |

The Vickers hardness of the coated rods were tested under 50 g load and compared to film deposited using conventional methods:

TABLE 3
VICKERS HARDNESS

| Film deposited | | Film deposited by |
|---|---|---|
| according to the | Polycrystalline alumina | conventional magnetron |
| present invention | substrate without film | sputtering (1) |
| 2500-3500 kg/mm² | About 2000 kg/mm² | 786-808 kg/mm² |

(1) Jones et al. J.Vac.Sci.Technol.,A, vol.7,No.3, May/June, 1989, p. 1245.

The coated rods were impacted in an ultrasonic welding machine and the worn area measured after a certain number of impacts was used to assess wear resistance. The worn area of coated rods was compared with the worn area Aₒ, for on uncoated rods under identical conditions, with the results shown in Table 4

TABLE 4
WEAR RESISTANCE

| Number | |
|---|---|
| of | Worn area for |
| impacts | coated rods |
| 11600 | 0.75 Aₒ |
| 23200 | 0.88 Aₒ |
| 34800 | 1.07 Aₒ |

As shown in Table 4, the Vickers hardness of alumina film obtained by the present method is significantly higher (about 400%) than Vickers hardness of similar film obtained using conventional methods. Moreover, as seen in Table 4, the alumina film deposited in accordance with the present invention improves the wear resistance since the worn area at the same number of impacts is about 25% less for the coated rods. This is highly advantageous for such applications like ceramic capillars used in welding machines for making integrated circuits.

### EXAMPLE 7

In this example, non-metallic and metallic surfaces such as, Al, Mg and their alloys, plastic materials, are treated to improve their adhesion after gluing. By virtue of the sputtering treatment, carried out in accordance with the present invention, the above material adhere to each other much better, than without treatment. The treatment is carried out in two steps. In the first step, the substrate made of one of the above materials, is bombarded with an ion plasma. By virtue of this bombardment the surface of the substrate is cleaned of molecules of organic residuals, products of corrosion etc. This treatment also activates the surface chemical bonds.

The conditions for ion bombardment are as follows:

| | |
|---|---|
| Voltage | 4 kV |
| Discharge current | 40 mA |
| Target working area | 100 cm² |
| Distance between the target and the substrate | 120 mm |
| Substrate temperature | 40 degrees C. |
| Gas | Nitrogen |
| Gas pressure | 5 × 10⁻³ mbar |
| Time of bombardment | 15 min |

The magnetic field strength between target and substrate is adjusted to zero. The plasma spreads easily across the whole substrate. High voltage and low discharge current ensure efficient ion bombardment at low temperature.

During the second step a film made of AlN or Alumina is deposited on the substrate. This film protects the substrate from corrosion and stabilizes the activated condition of its surface before adhesion. Conditions of the second step are as follows:

| | |
|---|---|
| Voltage | 2 kV |
| Discharge current | 400 mA |
| Magnetic field strength | 8 kA/m |
| Target working area | 100 cm² |
| Distance between the target and the substrate | 120 mm |
| Substrate temperature | 60° C. |
| Gas | Nitrogen |
| Gas pressure | 5 × 10⁻³ mbar |
| Time of deposition | 60 min |
| Thickness of film made of AIN | 2000 Angstrom |

The second step is carried out immediately after the first step without breaking vacuum in the apparatus. This prevents possible corrosion of the cleaned substrate and shortens the whole procedure.

The strong magnetic field plasma is focused locally which reduces possible harmful thermo-chemical influences on the substrate.

The adhesion characteristics were assessed by measuring the shear stress required to separate glued (coated and uncoated) substrates, with the results shown in Table 5:

TABLE 5

| Substrate Material | Deposition of film | Shear stress (kg/cm²) |
|---|---|---|
| Aluminum alloy 2024 | None | 128 |
| Aluminum alloy 2024 | Alumina film | 360 |
| Aluminum alloy 2024 | AIN film | 380 |
| Mg alloy AZ91 | None | 156 |
| Mg alloy AZ91 | Alumina film | 224 |
| Mg alloy AZ91 | AIN film | 218 |
| Mg alloy AM50 | None | 131 |
| Mg alloy AM50 | Alumina film | 185 |
| Mg alloy AM50 | AIN film | 182 |
| Fiberglass | None | 61 |
| Fiberglass | Alumina film | 103 |
| Fiberglass | AIN film | 105 |

As can be seen from Table 5, substrates coated in accordance with the present method has 1.5-3 times improved adhesion in comparison with the adhesion of uncoated substrates of the same material.

Referring now to FIG. 9(A), there is schematically illustrated apparatus of the present invention wherein the distance between cathode and substrate is 60 mm. The parameters of the process used are described in Example 3. The magnetic field was established either by permanent magnet or by electric magnet. The magnetic field strength H₁ was configured in such a manner that on the anode it was 30.8 kA/m or 20.8 kA/m (permanent or electric magnet, respectively) and on the target it was 7.2 kA/M or 9.6 kA/m. The magnetic strength was measured between anode and cathode in points 1, 2, 3, 4, 5, 6, 7, 8, 9 along arcuate trajectory 1, starting from point 1 (anode) and finishing at point 9 (target). The results are shown in FIGS. 9(B) and 9(C). The value of magnetic field strength at point 9 (cathode) was either 7.2 kA/m (for permanent magnet) or 9.6 kA/m (for electric magnet). The value of magnetic field strength at point 1 (anode) as either 30.8 kA/m (permanent magnet) or 20.8 kA/m (electric magnet). In other words, the magnetic field strength in the vicinity of the anode exceeded the magnetic field strength of the vicinity of the cathode either by 4.28 times or by 2.17 times respectively. By virtue of this magnetic strength gradient, it was possible to keep the temperature of the substrate in the range of 107-113° C. yielding advantageous properties of silica coatings.

In FIG. 10, there is shown another modification of a deposition device in accordance with the present invention employing a flat target. In this device, silica was deposited onto a glass substrate. The electrical conditions were similar to those of Example 3. However, the magnetic field was configured in such a manner that magnetic field strength on the anode was 16 kA/m and on the target 11 kA/m. Values of the magnetic field strength along the Z axis were measured and are presented geographically in FIGS. 10(B) and 10(C). It can be realized that magnetic field strength on the anode exceeds that of the target by 1.45 times. Beneficial properties of the coating obtained in accordance with the above conditions were similar to those disclosed herein.

As noted in Examples 1, 3 and elsewhere herein, the magnetic field strength on the anode and the cathode varies considerably (40 kA/m and 12 kA/m, respectively). The factor for these values is 3.33. There is also noted that the magnetic strength in the vicinity of anode is about 10-100 kA/m. The factor for these values is about 1.25-10. Therefore, the factor can vary between 1.25-10 and its preferable range is about 1.25-4.28. This gradient factor is of primary significant in obtaining improved coating results.

The present invention should not be limited to the above preferred embodiments and it should be understood that changes and modifications can be made by one ordinarily skilled in the art, without deviation of the scope of the invention, as will be defined below in the appended claims.

What is claimed is:

1. Sputtering apparatus for coating a substrate comprising:
a vacuum chamber containing an atmosphere of ionizable fluid at a uniform reduced pressure;
a cathode, defined by an outwardly facing surface, constituting a target, composed of material to be ejected therefrom;
an anode, insulated electrically from said cathode and situated within said vacuum chamber, said anode and said cathode provide a diode arrangement;
an electric power supply for applying electrical potential between said target and said anode, sufficient for establishing and maintaining a self sustained plasma glow discharge therebetween;
at least one substrate mounted within said chamber and positioned to receive target material flux ejected from said target;
means for supplying and removing ionizable fluid from said chamber to control the atmosphere of said fluid in said chamber sufficient to maintain a glow discharge between said cathode and anode;
a magnetic field generator within said chamber;
said magnetic field generator including means for generating a magnetic field in the vicinity of said anode which is greater than the magnetic field in the vicinity of the cathode thereby creating a magnetic field gradient of at least 1.25 times;
whereby the generated plasma is directed away from said substrate thereby maintaining the temperature of said substrate at a reduced level.

2. The apparatus of claim 1, further including a pressure control means adapted to monitor pressure within the said chamber in accordance with the variation of parameters of said electrical power supply and/or said magnetic field generator.

3. The apparatus of claim 1, wherein said target comprises a metallic element and said ionizable fluid comprises a mixture of argon and oxygen.

4. The apparatus of claim 1, wherein said target is the outwardly facing surface of said cathode, said anode surrounds said cathode; said substrate carried by a holder; said substrate holder having a plurality of holding stations for receiving a plurality of substrates; said cathode, said anode and said substrate holder being arranged such that the centers of symmetry of said target surface and said substrate holder coincide and lie on said central axis of symmetry of said anode.

5. The apparatus of claim 1, wherein the outwardly facing surface of said cathode pole is formed as a spherical segment and said substrate holder is formed as a truncated icosahedron.

6. The apparatus of claim 1, wherein the magnetic strength gradient is about 1.25-4.5.

7. The apparatus of claim 1, wherein the magnetic field strength in the vicinity of the anode is about 20-35 kA/m and the magnetic field in the vicinity of the cathode is about 5-10 kA/m.

8. A method for making a coated article of manufacture using the apparatus of claim 1 comprising the steps:
forming a coating on the surface of said substrate by the interaction of material sputtered from said cathode target with the ionized reactive fluid in said chamber; whereby said substrate temperature is maintained below about 300° C. without the use of coolant.

9. The method of claim 8, wherein said substrate temperature is maintained between about 40° C. and 200° C.

10. The method of claim 8, further including the step 4 maintaining a magnetic field gradient for localization of plasma within a region separated from said substrate by about 3 cm or more.

11. The method of claim 10, wherein said magnetic field gradient separates said plasma from said substrate by about 5 to 10 cm, or more.

12. A coated article of manufacture made in accordance with the method of claim 9, wherein said compound depositing onto said substrate is of the oxide type.

13. The coated article of manufacture of claim 10, in the form of a mold for the manufacture of optical articles, said substrate being made of glass and said coating comprising SiO₂.

14. The coated article made in accordance with the method of claim 10.

15. The coated article made in accordance with the method of claim 11.
